(19) United States
(12) Patent Application Publication
(10) Pub. No.: US 2024/0381592 A1
(43) Pub. Date: Nov. 14, 2024

(54) Switchgear Cabinet for Power Electronics

(71) Applicant: Siemens Aktiengesellschaft, München (DE)

(72) Inventors: Martin Kautz, Erlangen (DE); Karl Fleisch, Erlangen (DE); Volker Müller, Nürnberg (DE); Vladimir Danov, Erlangen (DE); Manfred Wohlfart, Wiesenthau (DE); Falk Rothe, Hemhofen (DE)

(73) Assignee: Siemens Aktiengesellschaft, München (DE)

(21) Appl. No.: 18/564,272

(22) PCT Filed: Apr. 19, 2022
(86) PCT No.: PCT/EP2022/060217

§ 371 Date: Nov. 27, 2023

(30) Foreign Application Priority Data
May 27, 2021 (EP) 21176257.0

(51) Int. Cl. H05K 7/20

(52) U.S. Cl. CPC H05K 7/20927; H05K 7/20572; H05K 7/20645

(57) ABSTRACT

Various teachings of the present disclosure include a switchgear cabinet for power electronics. An example cabinet may include a cooling apparatus for cooling the power electronics including a main cooling circuit and a secondary cooling circuit for a cooling medium. The secondary cooling circuit includes a heat exchanger arranged on a rear wall and/or between rails of the switchgear cabinet.

### CROSS-REFERENCE TO RELATED APPLICATIONS

This application is a U.S. National Stage Application of International Application No. PCT/EP2022/060217 filed Apr. 19, 2022, which designates the United States of America, and claims priority to EP application Ser. No. 21/176,257.0 filed May 27, 2021, the contents of which are hereby incorporated by reference in their entirety.

### TECHNICAL FIELD

The present disclosure relates to power electronics. Various embodiments of the teachings herein include switchgear cabinets.

### BACKGROUND

Switchgear cabinets are typically used as an installation site for electrical components. By this means, the components are protected against environmental influences and in addition, a defined personnel protection can thereby be ensured. By way of example, switchgear cabinets comprise, as components, information technology, control systems, power electronics, in particular, power converter technology and/or frequency converter technology, switches, protective devices and/or fuses and combinations thereof.

During operation, assemblies and components heat up within the switchgear cabinet. An active cooling system is often employed. From this, there arise two fundamental requirements. Firstly, switchgear cabinets should become ever more compact. Secondly, however, the waste heat increases, due to increasing capacities and power output, and this must be conducted away. Thus, an efficient and integrated cooling of switchgear cabinets, particularly for power electronics, in the most compact possible installation space, is to be aimed for. In particular, in the absence of an over-dimensioned cooling system, additional heat load resulting from new functions cannot be conducted away from the switchgear cabinet without difficulty. For this purpose, a complete redesign of the existing cooling system would be required.

### SUMMARY

The teachings of the present disclosure may be used to provide a switchgear cabinet with an improved cooling system. For example, some embodiments of the teachings herein include a switchgear cabinet (1) for power electronics (2), comprising a cooling apparatus (4) for cooling the power electronics and a heat exchanger (42), wherein the cooling apparatus (4) has a main cooling circuit and a secondary cooling circuit for a cooling medium and the heat exchanger (42) is arranged within the secondary cooling circuit, characterized in that the heat exchanger (42) is arranged on a rear wall (40) and/or between rails (41) of the switchgear cabinet (1).

In some embodiments, the heat exchanger (42) is designed as a recooler.

In some embodiments, the heat exchanger (42) comprises one or more ribbed pipes.

In some embodiments, the heat exchanger (42) comprises one or more plate heat exchangers designed in a cushion-like manner.

In some embodiments, an add-on wall is arranged on the rear side (40) of the switchgear cabinet (1), wherein the add-on wall comprises the heat exchanger (42).

In some embodiments, the add-on wall comprises one or more flow panels for directing the flow of air within the switchgear cabinet (1).

In some embodiments, the add-on wall comprises one or more protective panels for the protection of the power electronics (2), wherein the protective panels face toward the power electronics (2) and are arranged between the power electronics (2) and the heat exchanger (42).

In some embodiments, the add-on wall comprises a mounting surface for electronic and/or mechanical components of the switchgear cabinet (1).

In some embodiments, the branching of the secondary cooling circuit from the main cooling circuit is arranged in a lower region of the switchgear cabinet (1).

In some embodiments, the fluidic connection between the main cooling circuit and the secondary cooling circuit is designed to be non-destructively releasable.

In some embodiments, the secondary cooling circuit comprises control elements for adjusting the volume flow within the secondary cooling circuit.

In some embodiments, the heat exchanger (42) is arranged within a rectangular installation space (41) between the rails, wherein the installation space between the rails has a ratio of depth to length of not more than 0.1.

In some embodiments, the heat exchanger (42) is arranged within an installation space of the rear wall (40), wherein the installation space of the rear wall (40) has a ratio of depth to length of not more than 0.05.

In some embodiments, the heat exchanger (42) has a length of not more than 1000 mm, a width of not more than 290 mm and a depth of not more than 20 mm.

As another example, some embodiments include a method for producing a switchgear cabinet (1) for power electronics (2), comprising a cooling apparatus (4) for cooling the power electronics and a heat exchanger (42), wherein the cooling apparatus (4) has a main cooling circuit and a secondary cooling circuit for a cooling medium and the heat exchanger (42) is arranged within the secondary cooling circuit, characterized in that the heat exchanger (42) is arranged on a rear wall (40) and/or between rails (41) of the switchgear cabinet (1).

### BRIEF DESCRIPTION OF THE DRAWINGS

Further advantages, features, and details of the teachings herein will become apparent from the description below of exemplary embodiments and from the drawings. Schematically in the drawings:

FIG. 1 shows a switchgear cabinet incorporating teachings of the present disclosure; and

FIG. 2 shows a switchgear cabinet incorporating teachings of the present disclosure.

Parts which are identical or have the same value or act identically can be provided in one of the figures or in the figures with the same reference characters.

### DETAILED DESCRIPTION

The teachings of the present disclosure include switchgear cabinets for power electronics comprises a cooling apparatus for cooling the power electronics and a heat exchanger, wherein the cooling apparatus has a main cooling circuit and a secondary cooling circuit for a cooling medium and the heat exchanger is arranged within the secondary cooling circuit. In some embodiments, the switchgear cabinet is characterized in that the heat exchanger is arranged on a rear wall and/or between rails of the switchgear cabinet.

In some embodiments, the switchgear cabinet therefore has two cooling circuits. The first cooling circuit (main cooling circuit) corresponds, for example, to the known and/or already existing cooling system in the switchgear cabinet. The additional heat exchanger according to the invention is integrated into the second cooling circuit, i.e. in the secondary cooling circuit, which therefore forms a parallel bypass in relation to the main circuit. By this means, the heat exchanger can, be integrated and arranged in already existing switchgear cabinets that have a cooling apparatus. The already existing cooling concept of the original switchgear cabinet is thereby not substantially impaired. The secondary cooling circuit is therein designed so that it has no, or only very slight, effects on the main cooling circuit. Therein, the pressure loss over the secondary cooling circuit can, in principle, be adjusted and/or adapted to the main cooling circuit, for example by means of screens.

Furthermore, the heat exchanger which, in respect of an already existing switchgear cabinet, is an additional heat exchanger, is arranged on the rear wall of the switchgear cabinet and/or between its rails. As a result thereof, no additional installation space is needed for the heat exchanger. In other words, known switchgear cabinets typically have an installation space on their rear wall and/or between their rails, which is used for the heat exchanger of the secondary cooling circuit. As a result, a complete redesign of the switchgear cabinet with respect to its cooling, with additional loads, is not required. Technically, the heat exchanger can be arranged in the installation space on the rear wall and/or between the rails. With the arrangement according to the invention of the heat exchanger on the rear wall and/or between the rails of the switchgear cabinet, previously unused installation space is utilized. Additional installation space is therefore not necessary, although it can be provided.

By way of the heat exchanger and/or the additional heat exchanger (if the cooling apparatus already comprises a heat exchanger), the switchgear cabinet temperature (interior temperature) is reduced, so that an improved cooling, in particular of secondary assemblies, is achieved. In this way, their lifespan becomes extended.

Furthermore, the construction, design and apportioning of an existing switchgear cabinet, particularly a purely air-cooled switchgear cabinet can be transferred to a liquid-cooled system without installation space having to be reserved for further or additional components. In this case, the cooling medium is preferably a liquid, in particular water.

Some embodiments of the teachings herein include a method for producing a switchgear cabinet for power electronics, comprising a cooling apparatus for cooling the power electronics and a heat exchanger, wherein the cooling apparatus has a main cooling circuit and a secondary cooling circuit for a cooling medium and the heat exchanger is arranged within the secondary cooling circuit, is characterized in that the heat exchanger is arranged on a rear wall and/or between rails of the switchgear cabinet.

In particular, the switchgear cabinet incorporating teachings of the present disclosure can be produced from already existing switchgear cabinets which have a cooling apparatus, in particular a liquid cooling system. In other words, by way of the methods described herein, existing switchgear cabinets can be upgraded to a switchgear cabinet incorporating teachings of the present disclosure.

There result advantages and/or embodiments of the methods incorporating the teachings herein equivalent to those of the switchgear cabinets described herein.

In some embodiments, the heat exchanger is designed as a recooler. By this means, further waste heat can advantageously be conducted away.

In some embodiments, the heat exchanger comprises one or more ribbed pipes. The heat exchanger may comprise a ribbed pipe, i.e. as a pipe having ribs. Thereby, the cooling of the switchgear cabinet and/or its components is further improved. In particular, the ribbed pipes are herein flowed through by the cooling medium of the secondary cooling circuit. Ribbed pipes typically have a low pressure loss for an airflow within a switchgear cabinet. By this means, an air flow already existing within the switchgear cabinet, and possibly provided, is made use of and is simultaneously influenced as little as possible (additional passive cooling).

In addition, a fan for a targeted flow guidance to and/or away from the heat exchanger, and thus from the ribbed pipes, can be provided. Herein, the heated switchgear cabinet air is guided through the spatial region of the heat exchanger (additional active cooling). In other words, the switchgear cabinet can have an additional active and/or passive air cooling by way of the heat exchanger. In addition, ribbed pipes are cost-effective. Costly continuously cast cooling bodies are therefore not necessary, although they can be provided. Furthermore, the heat exchanger can be produced additively, in particular by means of a 3D printing method.

In some embodiments, the heat exchanger comprises one or more cushion-like plate heat exchangers. In some embodiments, the heat exchanger is designed as a cushion-like plate heat exchanger. By this means, the heat exchanger effectively has a plurality of inflated cushions through which the cooling medium flows. Such cushion-like plate heat exchangers are relatively flat, so that they can be arranged on the rear wall and/or between the rails of the switchgear cabinet. The cushion-like plate heat exchangers are also designated thermoplate or pillow-plate. In other words, the heat exchanger may be designed as a thermoplate and/or a pillow plate.

In some embodiments, an add-on wall is arranged on the rear side of the switchgear cabinet, wherein the add-on wall comprises the heat exchanger. In other words, the rear wall of the switchgear cabinet is designed as an add-on wall or it comprises such an add-on wall. By way of the add-on wall, the assembly of the heat exchanger, the control of the air stream and/or the installation of further components is improved. In other words, the add-on wall serves as a mounting surface for electrical, in particular electronic and/or mechanical components, that are functionally required within the switchgear cabinet.

In some embodiments, the add-on wall comprises one or more flow panels for the direction of flow of air within the switchgear cabinet. The flow of the air within the switchgear cabinet and in the region of the heat exchanger can thereby be set and controlled. In other words, the flow panels enable an air guidance. Furthermore, they serve as protection for the electrical installation space against splashed water and/or liquids. For this purpose, the flow panels are arranged, in particular, between the electrical installation space and the heat exchanger.

In some embodiments, the add-on wall comprises one or more protective panels to protect the power electronics, wherein the protective panels face the power electronics and are arranged between the power electronics and the heat exchanger. The flow panels can be designed as protective panels. Furthermore, the protective panels can also serve to guide the air stream. The protective panels that are arranged on the add-on wall and/or are included by it additionally protect the power electronics. By this means, the operational reliability is enhanced, in particular if the heat exchanger is retroactively installed on the rear wall and/or between the rails.

In some embodiments, the add-on wall comprises a mounting surface for electronic and/or mechanical components of the switchgear cabinet. Thereby the add-on wall can be used as a mounting wall for the aforementioned components. By this means, an additional mounting wall is provided. Furthermore, the components arranged, i.e. mounted, can be better cooled due to their proximity to the heat exchanger. In addition, the switchgear cabinet can be designed more compact.

In some embodiments, the branching of the secondary cooling circuit from the main cooling circuit is arranged in a lower region of the switchgear cabinet. Conduits for the main cooling circuit are typically arranged in a lower part of the switchgear cabinet. In addition, by way of the arrangement of the branching in the lower region of the switchgear cabinet, leaks close to the current-carrying components are prevented. The conduits of the main cooling circuit and the secondary cooling circuit typically extend as otherwise fluid-tight pipes through the switchgear cabinet.

In some embodiments, the fluidic connection between the main cooling circuit and the secondary cooling circuit is configured to be non-destructively releasable. For example, the fluidic connection is formed by way of a T-piece. By way of the non-destructively releasable connection, existing switchgear cabinets can also be extended to a switchgear cabinet according to the invention through the provision of a secondary cooling circuit and the arrangement of a heat exchanger integrated therein on the rear wall and/or between the rails of the switchgear cabinet.

In some embodiments, the secondary cooling circuit comprises control elements for adjusting the volume flow within the secondary cooling circuit. By this means, it can be ensured that the volume flow and/or the mass flow via the secondary cooling circuit is not too great. The control elements can be designed as screens.

In some embodiments, the heat exchanger is arranged within a rectangular installation space between the rails, wherein the installation space between the rails has a ratio of depth to length of not more than 0.1. Furthermore, the heat exchanger may be arranged within an installation space of the rear wall, wherein the installation space of the rear wall has a ratio of depth to length of not more than 0.05.

In some embodiments, the heat exchanger has the aforementioned ratios. By this means, it is designed particularly flat and is adapted as optimally as possible to the available installation space on the rear wall and/or the installation space between the rails.

In some embodiments, the heat exchanger has a length of not more than 1000 mm, a width of not more than 290 mm and a depth of not more than 20 mm. The heat exchanger is thereby adapted to the typical sizes of free installation spaces on the rear wall and/or between the rails of the switchgear cabinet.

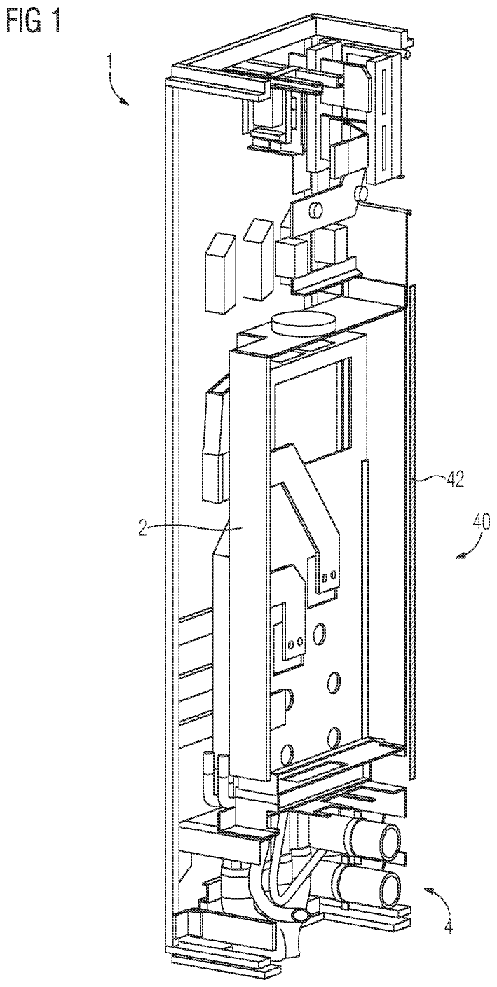

FIG. 1 shows an example switchgear cabinet 1 incorporating teachings of the present disclosure in a three-dimensional representation. The switchgear cabinet 1 comprises a cooling apparatus 4. The cooling apparatus 4 is arranged in a lower region, i.e. close to the bottom of the switchgear cabinet 1. In other words, the current-carrying components/assembly of the switchgear cabinet are arranged above the cooling apparatus 4 so that in the event of leaks from the pipes/conduits shown, these are not affected. The cooling apparatus 4 typically comprises further cooling components. In FIG. 1, the cooling apparatus 4 is symbolized by the two pipes shown, which are provided for a feeding and discharging of a cooling medium, in particular water.

In addition, in FIG. 1, a shaded region 42 is shown which indicates an installation space between the rails of the switchgear cabinet 1 and on a rear wall 40 of the switchgear cabinet 1. A heat exchanger, in particular a ribbed pipe, is arranged within the region 42. Thus, the heat exchanger is also indicated with the reference character 42.

The heat exchanger 42 is thus arranged in an installation space of the switchgear cabinet 1 that is unused in known switchgear cabinets. Furthermore, the heat exchanger 42 is connected by way of a secondary cooling circuit to the main cooling circuit (symbolized by the pipe in the lower region) and is thereby supplied with cooling medium, in particular water. In some embodiments, the join, i.e. the fluidic connection between the secondary cooling circuit and the main cooling circuit, can take place by means of a T-piece.

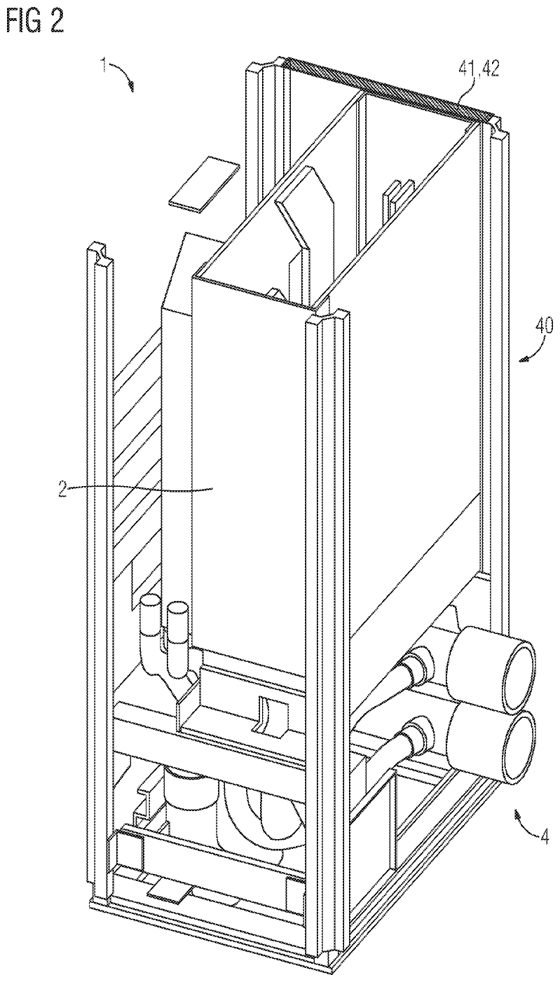

FIG. 2 shows a schematic three-dimensional representation of another example switchgear cabinet 1 incorporating teachings of the present disclosure. Herein, the difference from FIG. 1 is that the heat exchanger 42 is arranged in an upper region between the rails of the switchgear cabinet 1. In FIG. 1, it is arranged on the rear wall and laterally between the rails. Thus, the statements made in relation to FIG. 1 apply also for the embodiment shown in FIG. 2. The heat exchanger 42 could also be arranged on the rear wall 40 and/or a further heat exchanger could be provided which is arranged on the rear wall 40. In other words, the switchgear cabinet 1 preferably comprises two heat exchangers, wherein one of the heat exchangers is arranged on the rear wall 40 of the switchgear cabinet 1 and the further heat exchanger is arranged between the rails of the switchgear cabinet 1 in the shaded intermediate region 41.

Although the teachings herein have been illustrated and described in detail by way of the exemplary embodiments, the scope of the disclosure is not restricted by the examples given or other variations can be derived therefrom by a person skilled in the art without departing from the protective scope thereof.

### REFERENCE CHARACTERS

1 Switchgear cabinet
2 Power electronics
4 Cooling unit
40 Rear wall
41 Intermediate region
42 Heat exchanger

What is claimed is:

1. A switchgear cabinet for power electronics, the cabinet comprising:
a cooling apparatus for cooling the power electronics including a main cooling circuit and a secondary cooling circuit for a cooling medium;
wherein the secondary cooling circuit includes a heat exchanger arranged on a rear wall and/or between rails of the switchgear cabinet.

2. The switchgear cabinet as claimed in claim 1, wherein the heat exchanger comprises a recooler.

3. The switchgear cabinet as claimed in claim 1, wherein the heat exchanger comprises a ribbed pipes.

4. The switchgear cabinet as claimed in claim 1, wherein the heat exchanger comprises a cushion plate heat exchanger.

5. The switchgear cabinet as claimed in claim 1, further comprising an add-on wall arranged on a rear side of the switchgear cabinet;
wherein the add-on wall includes the heat exchanger.

6. The switchgear cabinet as claimed in claim 5, wherein the add-on wall comprises a flow panel to direct airflow within the switchgear cabinet.

7. The switchgear cabinet as claimed in claim 5, wherein
the add-on wall comprises a protective panel for the protection of the power electronics;
the protective panel faces the power electronics and is arranged between the power electronics and the heat exchanger.

8. The switchgear cabinet as claimed in claim 5, wherein the add-on wall comprises a mounting surface for electronic and/or mechanical components of the switchgear cabinet.

9. The switchgear cabinet as claimed in claim 1, wherein branching of the secondary cooling circuit from the main cooling circuit is arranged in a lower region of the switchgear cabinet.

10. The switchgear cabinet as claimed in claim 1, wherein a fluidic connection between the main cooling circuit and the secondary cooling circuit is non-destructively releasable.

11. The switchgear cabinet as claimed in claim 1, wherein the secondary cooling circuit comprises control elements to adjust a volume flow within the secondary cooling circuit.

12. The switchgear cabinet as claimed in claim 1, wherein:
the heat exchanger is arranged within a rectangular installation space between the rails; and
the installation space between the rails has a ratio of depth to length of not more than 0.1.

13. The switchgear cabinet as claimed in claim 1,
the heat exchanger is arranged within an installation space of the rear wall;
the installation space of the rear wall has a ratio of depth to length of not more than 0.05.

14. The switchgear cabinet as claimed in claim 1, wherein the heat exchanger has a length of not more than 1000 mm, a width of not more than 290 mm, and a depth of not more than 20 mm.

15. A method for producing a switchgear cabinet for power electronics, the cabinet comprising a cooling apparatus for cooling the power electronics with a main cooling circuit and a secondary cooling circuit including a heat exchanger, the method comprising:
arranging the heat exchanger on a rear wall and/or between rails of the switchgear cabinet.
